(19) United States
(12) Patent Application Publication
(10) Pub. No.: US 2024/0276722 A1
(43) Pub. Date: Aug. 15, 2024

(54) SEMICONDUCTOR MEMORY DEVICE

(71) Applicant: SK hynix Inc., Icheon-si Gyeonggi-do (KR)

(72) Inventors: Won Geun CHOI, Icheon-si Gyeonggi-do (KR); Mi Seong PARK, Icheon-si Gyeonggi-do (KR); In Su PARK, Icheon-si Gyeonggi-do (KR); Jung Shik JANG, Icheon-si Gyeonggi-do (KR); Jung Dal CHOI, Icheon-si Gyeonggi-do (KR)

(73) Assignee: SK hynix Inc., Icheon-si Gyeonggi-do (KR)

(21) Appl. No.: 18/448,599

(22) Filed: Aug. 11, 2023

(30) Foreign Application Priority Data
Feb. 14, 2023 (KR) 10-2023-0019070

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

There are provided a semiconductor memory device and a manufacturing method of a semiconductor memory device. The semiconductor memory device includes: a plurality of conductive layers stacked to be spaced apart from each other in a first direction; a channel hole extending in the first direction to penetrate the plurality of conductive layers; two or more channel patterns disposed to be spaced apart from each other along a sidewall of the channel hole; and two or more memory patterns disposed to be spaced apart from each other between the sidewall of the channel hole and the two or more channel patterns, respectively.

### CROSS-REFERENCE TO RELATED APPLICATION

The present application claims priority under 35 U.S.C. § 119(a) to Korean patent application number 10-2023-0019070 filed on Feb. 14, 2023, in the Korean Intellectual Property Office, the entire disclosure of which is incorporated by reference herein.

### BACKGROUND

### 1. Technical Field

The present disclosure generally relates to an electronic device and a manufacturing method of an electronic device, and more particularly, to a semiconductor memory device and a manufacturing method of a semiconductor memory device.

### 2. Related Art

Semiconductor memory devices are applied to electronic devices in various fields, including automobiles, medical appliances, data centers, and the like, in addition to small electronic devices. Accordingly, demands for semiconductor memory devices have increased.

In order to achieve the large capacity of semiconductor memory devices, a three-dimensional semiconductor memory device has been proposed. The three-dimensional semiconductor memory device may include a plurality of memory cells arranged three-dimensionally.

### SUMMARY

In accordance with an embodiment of the present disclosure, there is provided a semiconductor memory device including: a stack structure including a plurality of conductive layers stacked to be spaced apart from each other in a first direction; a channel hole extending in the first direction to penetrate the plurality of conductive layers in the stack structure; an isolation structure including a core part disposed in a central region of the channel hole and an extension part protruding from the core part toward a sidewall of the channel hole, the isolation structure isolating the channel hole into two or more regions that are adjacent to the stack structure; a channel pattern disposed in each of the two or more regions of the channel hole; a memory pattern interposed between the channel pattern and the stack structure, the memory pattern including a first part and a second part, which protrude toward the extension part of the isolation structure; and an insulating layer filling a groove defined between the first part and the second part of the memory pattern.

In accordance with an embodiment of the present disclosure, there is provided a semiconductor memory device including: a stack structure including a plurality of conductive layers stacked to be spaced apart from each other in a first direction and a plurality of insulating patterns that are adjacent to the plurality of conductive layers in a second direction, the plurality of insulating patterns being stacked to be spaced apart from each other in the first direction; a plurality of channel holes extending in the first direction to penetrate the plurality of conductive layers in the stack structure; a cell plug formed in each of the plurality of channel holes, the cell plug including two or more channel patterns isolated from each other along a sidewall of each of the plurality of channel holes and two or more memory patterns disposed between the sidewall of each of the plurality of channel holes and the two or more channel patterns, respectively, the two or more memory patterns being isolated from each other; a plurality of auxiliary holes extending in the first direction to penetrate the plurality of insulating patterns in the stack structure; and a vertical structure including a tubular semiconductor layer disposed inside each of the plurality of auxiliary holes and a tubular vertical insulating layer disposed outside of the tubular semiconductor layer.

In accordance with an embodiment of the present disclosure, there is provided a method of manufacturing a semiconductor memory device, the method including: forming a preliminary stack structure including a plurality of first material layers and a plurality of second material layers, which are alternately disposed in a first direction; forming a channel hole extending in the first direction in the preliminary stack structure; forming a memory layer on a sidewall of the channel hole; forming a channel layer on an inner wall of the memory layer; isolating the channel layer into two or more channel patterns arranged along the sidewall of the channel hole such that a portion of the memory layer is exposed; etching the portion of the memory layer, thereby forming a groove at an etched surface of the memory layer; filling the groove with an insulating layer; isolating the memory layer into two or more memory patterns disposed between the sidewall of the channel hole and the two or more channel patterns, respectively, such that the plurality of second material layers are exposed; and replacing portions of the plurality of second material layers at the periphery of the channel hole with a plurality of conductive layers through the channel hole.

### BRIEF DESCRIPTION OF THE DRAWINGS

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a semiconductor memory device in accordance with an embodiment of the present disclosure.

FIG. 2 is a circuit diagram of a memory cell array in accordance with an embodiment of the present disclosure.

FIGS. 3A and 3B are views illustrating vertical arrangements of a semiconductor memory device in accordance with embodiments of the present disclosure.

FIGS. 4A and 4B are sectional views illustrating first and second structures of a semiconductor memory device in accordance with embodiments of the present disclosure.

FIG. 5 is a view illustrating a semiconductor memory device in accordance with an embodiment of the present disclosure.

FIG. 6 is a sectional view of the semiconductor memory device taken along line I-I′ shown in FIG. 5.

FIGS. 7A and 7B are enlarged plan views illustrating a cross-section of each of a cell plug and a vertical structure.

FIG. 8 is a plan view of a semiconductor memory device in accordance with an embodiment of the present disclosure.

FIGS. 9A and 9B illustrate enlarged cross-sections of a cell plug and a vertical structure in accordance with an embodiment of the present disclosure.

FIGS. 10A, 11A, 11B, 13A, 13B, 13C, 14, 15A, 16, 17A, and 17B are plan views illustrating a manufacturing method of a semiconductor memory device in accordance with an embodiment of the present disclosure.

FIGS. 10B, 12, 15B, and 17C are sectional views illustrating the manufacturing method of the semiconductor memory device in accordance with the embodiment of the present disclosure.

FIG. 18 is a block diagram illustrating an electronic system including a semiconductor memory device in accordance with embodiments of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first”, “second”, etc. may be used herein to describe various elements, these elements are not limited by these terms. These terms are used for distinguishing one element from another element and not to suggest a number or order of elements.

Embodiments of the present disclosure are directed to a semiconductor memory device and a manufacturing method of a semiconductor memory device, where the device and method are capable of increasing the degree of integration of memory cells and reducing the level of difficulty of a manufacturing process.

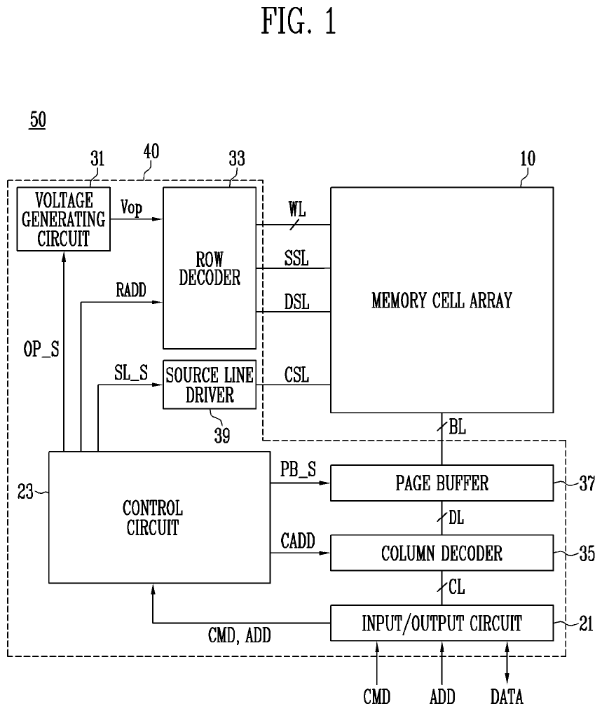

FIG. 1 is a block diagram illustrating a semiconductor memory device in accordance with an embodiment of the present disclosure.

Referring to FIG. 1, the semiconductor memory device 50 may include a peripheral circuit 40 and a memory cell array 10.

The peripheral circuit 40 may be configured to perform a program operation that stores data in the memory cell array 10, a read operation that outputs data stored in the memory cell array 10, and an erase operation that erases data stored in the memory cell array 10. In an embodiment, the peripheral circuit 40 may include an input/output circuit 21, a control circuit 23, a voltage generating circuit 31, a row decoder 33, a column decoder 35, a page buffer 37, and a source line driver 39.

The peripheral circuit 40 may be connected to the memory cell array 10 through a common source line CSL, bit lines BL, a drain select line DSL, word lines WL, and a source select line SSL.

The input/output circuit 21 may transfer, to the control circuit 23, a command CMD and an address ADD, which are received from an external device (e.g., a memory controller) of the semiconductor memory device 50. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate various operating voltages Vop used for a program operation, a read operation, and an erase operation in response to the operation signal OP_S.

The row decoder 33 may transfer the operating voltages Vop to the drain select line DSL, the word lines WL, and the source select line SSL in response to the row address RADD.

The column decoder 35 may transmit data DATA input from the input/output circuit 21 to the page buffer 37 or transmit data DATA stored in the page buffer 37 to the input/output circuit 21 in response to the column address CADD. The column decoder 35 may exchange data DATA with the input/output circuit 21 through a column line CL. The column decoder 35 may exchange data DATA with the page buffer through a data line DL.

The page buffer 37 may store read data received through the bit lines BL in response to the page buffer control signal PB_S. The page buffer 37 may sense a voltage or current of the bit lines BL in a read operation.

The source line driver 39 may control a voltage applied to the common source line CSL in response to the source line control signal SL_S.

The memory cell array 10 may include a plurality of memory blocks. Each of the memory blocks may include a plurality of memory cells arranged three-dimensionally. Each memory cell may be a nonvolatile memory cell. In an embodiment, each memory cell may be a NAND flash memory cell.

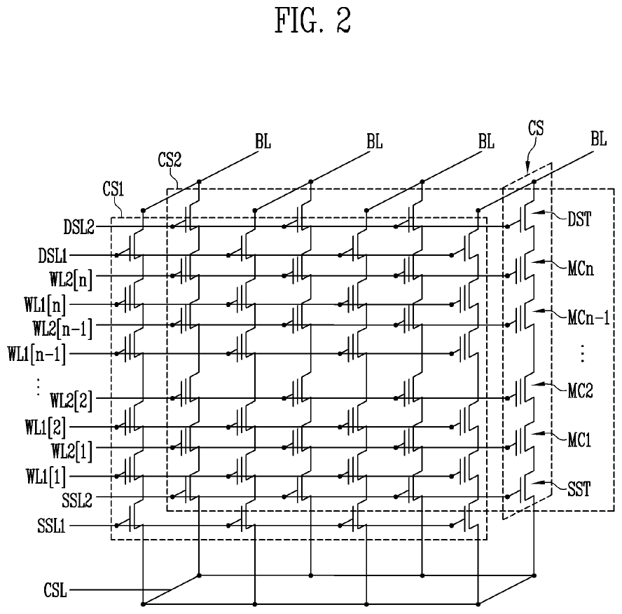

FIG. 2 is a circuit diagram of a memory cell array in accordance with an embodiment of the present disclosure.

Referring to FIG. 2, the memory cell array may include a plurality of memory cell strings CS. Each memory cell string CS may include at least one source select transistor SST, a plurality of memory cells MC1 to MCn (n is a natural number of 2 or more), and at least one drain select transistor DST. The plurality of memory cells MC1 to MCn may be connected in series between the source select transistor SST and the drain select transistor DST. The source select transistor SST, the plurality of memory cells MC1 to MCn, and the drain select transistor DST may be connected in series by a channel pattern.

The plurality of memory cell strings CS may be connected in parallel with a common source line CSL. Each memory cell string CS may be connected to one corresponding bit line, among a plurality of bit lines BL. The common source line CSL and the plurality of bit lines BL may be connected to a plurality of channel patterns of the plurality of memory cell strings CS.

The plurality of memory cells MC1 to MCn of the memory cell string CS may be connected to the common source line CSL via the source select transistor SST. The plurality of memory cells MC1 to MCn of the memory cell string CS may be connected to a corresponding bit line BL via the drain select transistor DST.

The plurality of memory cell strings CS may include a plurality of first memory cell strings CS1 controlled by a first gate group and a plurality of second memory cell strings CS2 controlled by a second gate group. The first gate group may include at least one first source select line SSL1, a plurality of word lines WL1[1] to WL1[n] of a first group, and at least one first drain select line DSL1, which are connected to the plurality of first memory cell strings CS1. The second gate group may include at least one second source select line SSL2, a plurality of word lines WL2[1] to WL2[n] of a second group, and at least one second drain select line DSL2, which are connected to the plurality of second memory cell strings CS2.

Each of the first source select line SSL1 and the second source select line SSL2 may be used as a gate electrode of a corresponding source select transistor SST. Each group of the plurality of word lines WL1[1] to WL1[n] of the first group and the plurality of word lines WL2[1] to WL2[n] of the second group may be used as gate electrodes of a plurality of corresponding memory cells MC1 to MCn. Each of the first drain select line DSL1 and the second drain select line DSL2 may be used as a gate electrode of a corresponding drain select transistor DST.

The plurality of first memory cell strings CS1 and the plurality of second memory cell strings CS2 may be divided into a plurality of pairs. A first memory cell string CS1 and a second memory cell string CS2 of each pair may be connected to a corresponding bit line BL.

An operating voltage for precharging a channel pattern of a memory cell string CS corresponding to each bit line BL may be applied to the bit line BL. An operating voltage for discharging a channel potential of a memory cell string CS may be applied to the common source line CSL.

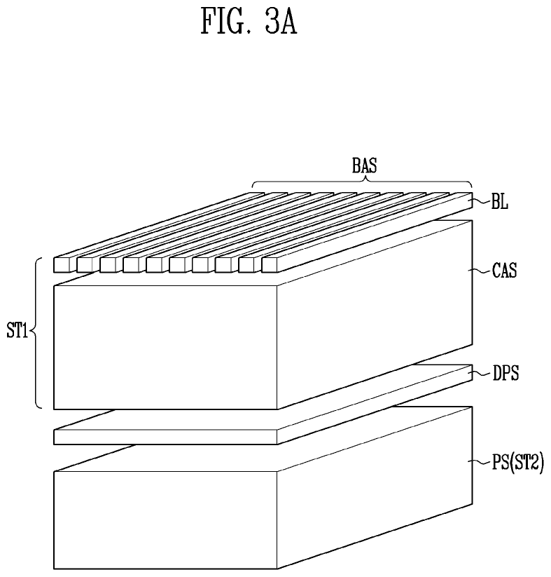

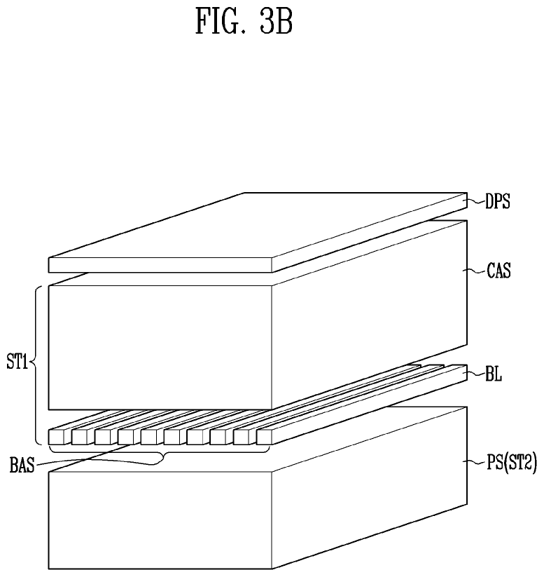

FIGS. 3A and 3B are views illustrating vertical arrangements of a semiconductor memory device in accordance with embodiments of the present disclosure.

Referring to FIGS. 3A and 3B, the semiconductor memory device may include a first structure ST1, a second structure ST2, and a doped semiconductor structure DSP. The first structure ST1 may include a cell array structure CAS and a bit line array structure BAS, and the second structure ST2 may include a peripheral circuit structure PS.

The bit line array structure BAS may include the plurality of bit lines BL described with reference to FIGS. 1 and 2.

The cell array structure CAS may be disposed between the bit line array structure BAS and the doped semiconductor structure DPS. The cell array structure CAS may include the memory cell array 10, shown in FIG. 1, and may include the plurality of memory cell strings CS, shown in FIG. 2.

The doped semiconductor structure DPS may be connected to the common source line CSL, shown in FIG. 1 or 2. The common source line CSL, shown in FIG. 1 or 2, may be connected to a channel pattern of a memory cell string via the doped semiconductor structure DPS. The doped semiconductor structure DPS may include at least one of an n-type impurity and a p-type impurity.

The peripheral circuit structure PS may include a region overlapping with the doped semiconductor structure DPS, the cell array structure CAS, and the bit line array structure BAS. The peripheral circuit structure PS may include a plurality of transistors, a capacitor, a resistor, and the like, which constitute the peripheral circuit 40, shown in FIG. 1.

The peripheral circuit PS may be adjacent to the doped semiconductor structure DPS as shown in FIG. 3A or may be adjacent to the bit line array structure BAS as shown in FIG. 3B.

Although not shown in the drawings, each of the first structure ST1 and the second structure ST2 may include at least one of a plurality of interconnections, a plurality of contacts, and a plurality of conductive bonding pads, which are used for electrical connection.

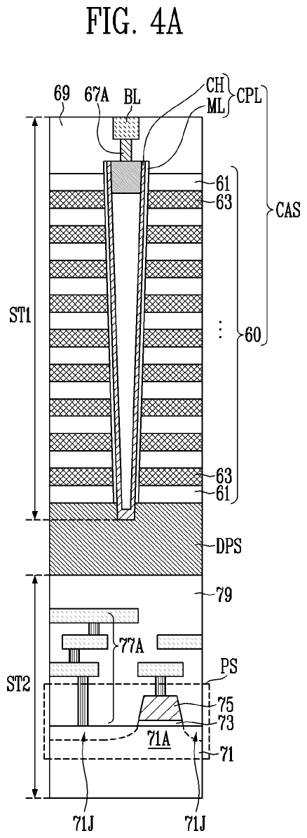

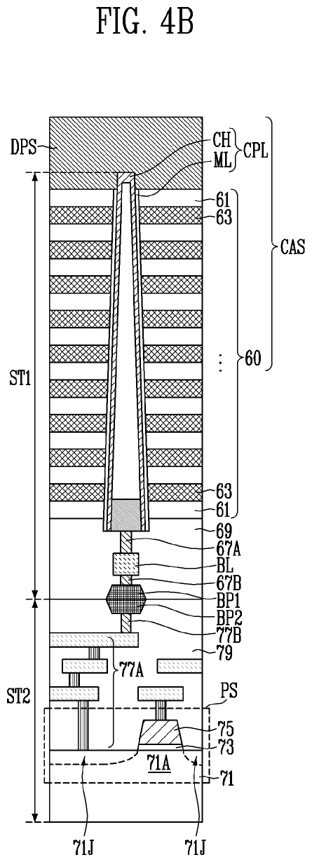

FIGS. 4A and 4B are sectional views illustrating first and second structures of a semiconductor memory device in accordance with embodiments of the present disclosure.

Referring to FIGS. 4A and 4B, the first structure ST1 may include the cell array structure CAS described with reference to FIGS. 3A and 3B, a first insulating structure 69, a bit line contact 67A, and the bit line BL described with reference to FIGS. 3A and 3B. The cell array structure CAS may include a stack structure 60 disposed between a doped semiconductor structure DPS and the bit line BL and a cell plug CPL penetrating the stack structure 60.

The stack structure 60 may include a plurality of insulating layers 61 and a plurality of conductive layers 63, which are alternately stacked in a direction in which the doped semiconductor structure DPS faces the bit line BL. The plurality of conductive layers 63 may form a source select line (e.g., SSL1 or SSL2, shown in FIG. 2), a drain select line (e.g., DSL1 or DSL2, shown in FIG. 2), and a plurality of word lines (e.g., WL1[1] to WL1[n] shown in FIG. 2 or WL2[1] to WL2[n] shown in FIG. 2).

The cell plug CPL may include a channel pattern CH and a memory pattern ML between the channel pattern CH and the stack structure 60. The channel pattern CH may be used as a channel region of the memory cell string CS, shown in FIG. 2. Some regions of the memory pattern ML may be used as data storage regions of the plurality of memory cells MC1 to MCn shown in FIG. 2.

The channel pattern CH may include an end portion connected to the doped semiconductor structure DPS. The channel pattern CH may be connected to the bit line BL via the bit line contact 67A. The bit line contact 67A and the bit line BL may be disposed inside the first insulating structure 69.

The second structure ST2 may include a semiconductor substrate 71, a peripheral circuit structure PS, a second insulating structure 79, and a plurality of interconnections 77A. The peripheral circuit structure PS may correspond to the peripheral circuit structure described with reference to FIGS. 3A and 3B.

The semiconductor substrate 71 may include an active region 71A partitioned by an isolation layer (not shown). The peripheral circuit structure PS may include a transistor. The transistor may include a gate insulating layer 73 and a gate electrode 75, which are stacked on the active region 71A of the semiconductor substrate 71, and source/drain junctions 71J formed in the active region 71A at both sides of the gate electrode 75. The plurality of interconnections 77A may include sub-interconnections individually connected to the gate electrode 75 and the source/drain junctions 71J.

The semiconductor substrate 71 and the peripheral circuit structure PS may be covered with the second insulating structure 79, and the plurality of interconnections 77A may be disposed inside the second insulating structure 79.

Referring to FIG. 4A, a process of forming the doped semiconductor structure DSP and a process of forming the first structure ST1 may be performed on the second structure ST2. In an embodiment, after the doped semiconductor structure DPS is formed on the second structure ST2, the process of forming the first structure ST1 may be performed on the doped semiconductor structure DPS.

Referring to FIG. 4B, the process of forming the first structure ST1 and a process of forming the second structure ST2 may be individually performed. The first structure ST1 may further include a first contact 67B and the first conductive bonding pad BP1, which are disposed in the first insulating structure 69, and the second structure ST2 may further include a second contact 77B and a second conductive bonding pad BP2, which are disposed in the second insulating structure 79. The first conductive bonding pad BP1 of the first structure ST1 and the second conductive bonding pad BP2 of the second structure ST2, which are provided through individual processes, may be connected to each other through a bonding process. The doped semiconductor structure DPS may be provided after the bonding process.

The first conductive bonding pad BP1 may be electrically connected to the bit line BL connected to the memory cell string or any one of the conductive layers 63 connected to the memory cell string via the first contact 67B. The second conductive bonding pad BP2 may be electrically connected to any one of elements constituting the peripheral circuit structure PS via the second contact 77B. FIG. 4B representatively illustrates the first contact 67B, the first conductive bonding pad BP1, the second conductive bonding pad BP2, and the second contact 77B, which are provided for electrical connection between a transistor constituting the page buffer 37, shown in FIG. 1, and the bit line BL. The bit line BL may be electrically connected to the first conductive bonding pad BP1 via the first contact 67B, and a sub-interconnection of one of the plurality of interconnections 77A may be electrically connected to the second conductive bonding pad BP2 via the second contact 77B.

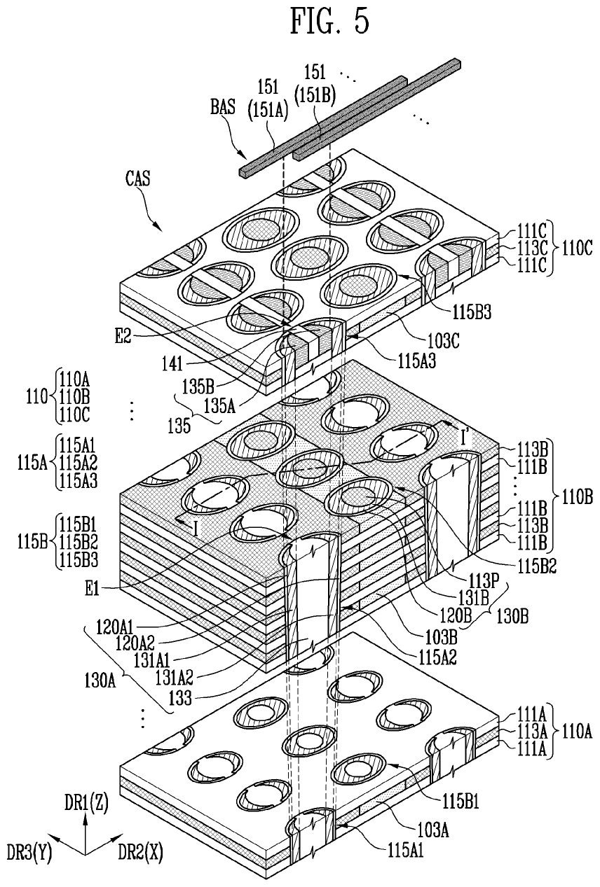

FIG. 5 is a view illustrating a semiconductor memory device in accordance with an embodiment of the present disclosure. A first direction DR1, a second direction DR2, and a third direction DR3, which are described herein, may be defined as directions in which the XYZ axes intersect. In an embodiment, the second direction DR2 may be an X-axis direction, the third direction DR3 may be a Y-axis direction, and the first direction DR1 may be a Z-axis direction.

Referring to FIG. 5, a cell array structure CAS of the semiconductor memory device may include a gate stack structure 110, a plurality of channel holes 115A penetrating the gate stack structure 110, a plurality of auxiliary holes 115B penetrating the gate stack structure 110, a plurality of cell plugs 130A respectively disposed inside the plurality of channel holes 115A, and a plurality of vertical structures 130B respectively disposed inside the plurality of auxiliary holes 115B. A bit line array structure BAS of the semiconductor memory device may include a plurality of bit lines 151.

The gate stack structure 110 may include a plurality of conductive layers 113A, 113B, and 113C stacked to be spaced apart from each other in the first direction DR1 and a plurality of insulating patterns 103A, 103B, and 103C stacked to be spaced apart from each other in the first direction DR1. The plurality of insulating patterns 103A, 103B, and 103C may be adjacent to the plurality of conductive layers 113A, 113B, and 113C in the second direction DR2. The gate stack structure 110 may further include a plurality of interlayer insulating layers 111A, 111B, and 111C alternately disposed in the first direction DR1 with the plurality of conductive layers 113A, 113B, and 113C. The plurality of interlayer insulating layers 111A, 111B, and 111C may extend in the second direction DR2 to overlap with the plurality of insulating patterns 103A, 103B, and 103C. Accordingly, the plurality of interlayer insulating layers 111A, 111B, and 111C may be alternately disposed in the first direction DR1 with the plurality of insulating patterns 103A, 103B, and 103C.

Each of the plurality of conductive layers 113A, 113B, and 113C, each of the plurality of insulating patterns 103A, 103B, and 103C, and each of the plurality of interlayer insulating layers 111A, 111B, and 111C may be formed in a plate shape extending in the second direction DR2 and the third direction DR3. In an embodiment, each of the plurality of conductive layers 113A, 113B, and 113C, each of the plurality of insulating patterns 103A, 103B, and 103C, and each of the plurality of interlayer insulating layers 111A, 111B, and 111C may have a plate shape extending along an XY plane.

The plurality of conductive layers 113A, 113B, and 113C may include at least one of a doped semiconductor layer, a metal layer, and a conductive metal nitride layer. The doped semiconductor layer may include a doped silicon layer. The metal layer may include tungsten, copper, molybdenum, and the like. The conductive metal nitride layer may include itanium nitride, tantalum nitride, and the like. The plurality of insulating patterns 103A, 103B, and 103C may be formed of an insulating material that is different from an insulating material of the plurality of interlayer insulating layers 111A, 111B, and 111C. The plurality of insulating patterns 103A, 103B, and 103C may be formed of an insulating material having an etch selectivity with respect to the plurality of interlayer insulating layers 111A, 111B, and 111C. In an embodiment, the plurality of interlayer insulating layers 111A, 111B, and 111C may include a silicon oxide layer, and the plurality of insulating patterns 103A, 103B, and 103C may include a silicon nitride layer.

The plurality of channel holes 115A may extend in the first direction DR1 to penetrate the plurality of conductive layers 113A, 113B, and 113C and the plurality of interlayer insulating layers 111A, 111B, and 111C in the gate stack structure 110. The plurality of auxiliary holes 115B may extend in the first direction DR1 to penetrate the plurality of insulating patterns 103A, 103B, and 103C and the plurality of interlayer insulating layers 111A, 111B, and 111C in the gate stack structure 110.

The gate stack structure 110 may include a first stack structure 110A, a second stack structure 110B, and a third stack structure 110C. Each channel hole 115A may include a first part 115A1 in the first stack structure 110A, a second part 115A2 in the second stack structure 110B, and a third part 115A3 in the third stack structure 110C. Each auxiliary hole 115B may include a first part 115B1 in the first stack structure 110A, a second part 115B2 in the second stack structure 110B, and a third part 115B3 in the third stack structure 110C. For convenience of recognition, FIG. 5 illustrates an exploded perspective view of the first stack structure 110A, the second stack structure 110B, and the third stack structure 110C. However, the second stack structure 110B may be disposed to be in contact with the first stack structure 110A, and the third stack structure 110C may be disposed to be in contact with the second stack structure 110B.

The plurality of conductive layers 113A, 113B, and 113C may include a first conductive layer 113A of the first stack structure 110A, a plurality of second conductive layers 113B of the second stack structure 110B, and a third conductive layer 113C of the third stack structure 110C. The plurality of insulating patterns 103A, 103B, and 103C may include a first insulating pattern 103A of the first stack structure 110A, a plurality of second insulating patterns 103B of the second stack structure 110B, and a third insulating pattern 103C of the third stack structure 110C. The plurality of interlayer insulating layers 111A, 111B, and 111C may include a first interlayer insulating layer 111A of the first stack structure 110A, a plurality of second interlayer insulating layers 111B of the second stack structure 110B, and a third interlayer insulating layer 111C of the third stack structure 110C.

The first conductive layer 113A of the first stack structure 110A may be isolated into the first source select line SSL1 and the second source select line SSL2, which are described with reference to FIG. 2, by the first insulating pattern 103A. The plurality of second conductive layers 113B of the second stack structure 110B may be isolated into the plurality of word lines WL1[1] to WL1[n] of the first group and the plurality of word lines WL2[1] to WL2[n] of the second group, which are described with reference to FIG. 2, by the plurality of second insulating patterns 103B. The third conductive layer 113C of the third stack structure 110C may be isolated into the first drain select line DSL1 and the second drain select line DSL2, which are described with reference to FIG. 2, by the third insulating pattern 103C.

Each cell plug 130A may include two or more channel patterns, for example, two channel patterns 131A1 and 131A2, and two or more memory patterns, for example, two memory patterns 120A1 and 120A2. The channel patterns 131A1 and 131A2 of the cell plug 130A may be isolated from each other along a sidewall of a corresponding channel hole 115A. The memory patterns 120A1 and 120A2 of the cell plug 130A may correspond one-to-one to and the channel patterns 131A1 and 131A2 of the cell plug 130A. The memory patterns 120A1 and 120A2 of the cell plug 130A may be disposed between the sidewall of the channel hole 115A and the channel patterns 131A1 and 131A2, respectively, and may be isolated from each other.

Each of the memory patterns 120A1 and 120A2 of the cell plug 130A may continuously extend along an inner wall of each of the first part 115A1, the second part 115A2, and the third part 115A3 of a corresponding channel hole 115A. Each of the channel patterns 131A1 and 131A2 of the cell plug 130A may extend along an inner wall of a corresponding memory pattern. Each of the channel patterns 131A1 and 131A2 of the cell plug 130A may continuously extend along an inner wall of each of the first part 115A1, the second part 115A2, and the third part 115A3 of a corresponding channel hole 115. Each channel pattern may be formed of a semiconductor material which can be used as a channel region of a memory cell string. In an embodiment, each channel pattern may include silicon (Si), germanium (Ge), or a mixture thereof.

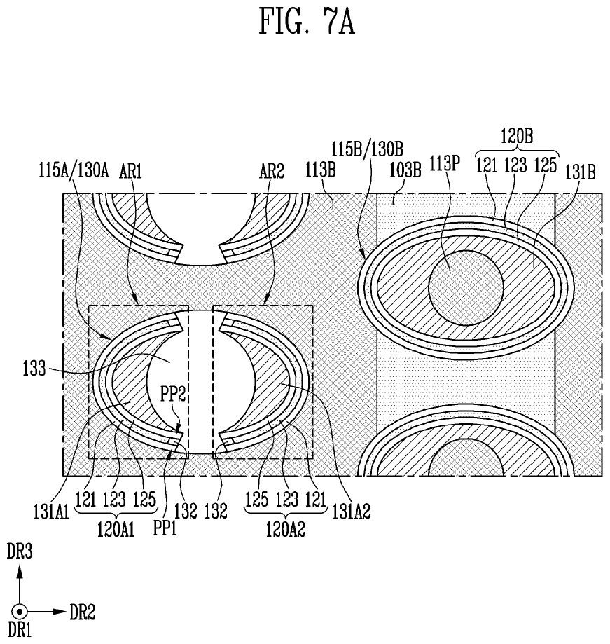

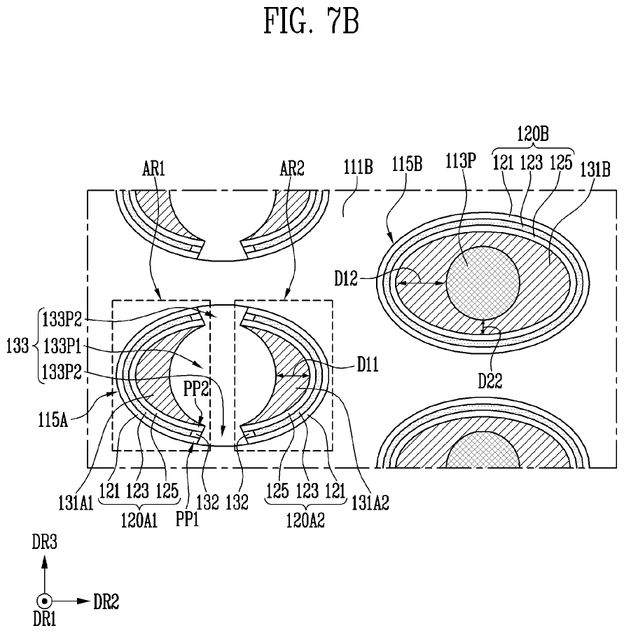

Each cell plug 130A may further include an isolation structure 133. The isolation structure 133 may include an insulating material. The isolation structure 133 may isolate a corresponding channel hole 115A into two or more regions. The isolation structure 133 may include an end portion E1 forming a common surface with a portion of a sidewall of the channel hole 115A. The isolation structure 133 may extend from the first part 115A1 to the second part 115A2 of the channel hole 115A. Each cell plug 130A may further include an insulating layer 132 which will be described later with reference to FIGS. 7A and 7B.

The semiconductor memory device may further include a doped capping layer 135 and an upper insulating layer 141. The doped capping layer 135 and the upper insulating layer 141 may be disposed at the third part 115A3 of a corresponding channel hole 115A. The doped capping layer 135 may be formed of a semiconductor layer including at least one of an n-type impurity and a p-type impurity. In an embodiment, the doped capping layer 135 may include the n-type impurity as a majority carrier. The doped capping layer 135 may be isolated into two or more doped capping patterns, for example, two doped capping patterns 135A and 135B, by the upper insulating layer 141. The two doped capping patterns 135A and 135B may be respectively in contact with inner sides of the two channel patterns 131A1 and 131A2. The upper insulating layer 141 may include an end portion E2 forming a common surface with a portion of a sidewall of a corresponding channel hole 115A. For example, when the isolation structure 133 has two end portions facing the third direction DR3 and the opposite direction thereof, the upper insulating layer 141 may also have two end portions facing the third direction DR3 and the opposite direction thereof.

The plurality of bit lines 151 may include bit lines individually connected to the two channel patterns 131A1 and 131A2 that are isolated from each other in each of the plurality channel holes 115A. In an embodiment, the two channel patterns 131A and 131A2 may include a first channel pattern 131A1 and a second channel pattern 131A2, and the plurality of bit lines BL may include a first bit line 151A connected to the first channel pattern 131A1 and a second bit line 151B connected to the second channel pattern 131A2. Although not shown in the drawing, each bit line 151 may be electrically connected to a corresponding channel pattern 131A1 or 131A2 via a bit line contact and a corresponding doped capping pattern 135A or 135B.

Each vertical structure 130B may include a conductive pillar 113P, a vertical insulating layer 120B, and a semiconductor layer 131B. The conductive pillar 113P may be disposed in a central region of a corresponding auxiliary hole 115B. The vertical insulating layer 120B may extend along a sidewall of the auxiliary hole 115B. The semiconductor layer 131B may be disposed between the vertical insulating layer 120B and the conductive pillar 113P. Each of the conductive pillar 113P, the vertical insulating layer 120B, and the semiconductor layer 131B may continuously extend along the first part 115B1, the second part 115B2, and the third part 115B3 of the auxiliary hole 115B.

The conductive pillar 113P may include the same conductive material as the plurality of conductive layers 113A, 113B, and 113C. In an embodiment, the conductive pillar 113P may include at least one of a doped semiconductor layer, a metal layer, and a conductive metal nitride layer. The doped semiconductor layer may include a doped silicon layer. The metal layer may include tungsten, copper, molybdenum, and the like. The conductive metal nitride layer may include titanium nitride, tantalum nitride, and the like. The semiconductor layer 131B may be formed in a tubular shape surrounding the conductive pillar 113P. The semiconductor layer 131B may include the same semiconductor material as the two channel patterns 131A1 and 131A2. In an embodiment, the semiconductor layer 131B may include silicon (Si), germanium (Ge), or a mixture thereof. The vertical insulating layer 120B may be disposed outside of the semiconductor layer 131B and may be formed in a tubular shape surrounding the semiconductor layer 131B. The vertical insulating layer 120B may include the same material layers as the two or more memory patterns 120A1 and 120A2.

Each auxiliary hole 115B may have substantially the same cross-sectional shape as each channel hole 115A. In an embodiment, each of the auxiliary hole 115B and the channel hole 115A may have an elliptical cross-section on an XY plane.

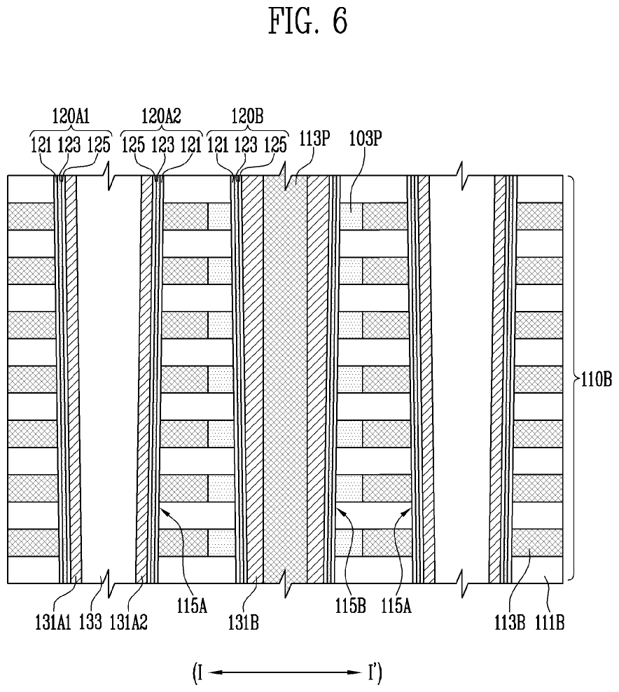

FIG. 6 is a sectional view of the semiconductor memory device taken along line I-I′, shown in FIG. 5. FIG. 6 illustrates a longitudinal sectional structure of each of the cell plug 130A and the vertical structure 130B, which are shown in FIG. 5. Also, FIG. 6 illustrates a portion of the cell plug 130A disposed at the second part of the channel hole 115A penetrating the second stack structure 110B and a portion of the vertical structure 130B disposed at the second part of the auxiliary hole 115B penetrating the second stack structure 110B.

Referring to FIG. 6, each of the memory patterns 120A1 and 120A2 of the cell plug may be interposed between a corresponding channel pattern, among the channel patterns 131A1 and 131A2 of the cell plug, and a stack structure (e.g., 110B).

Each of the vertical insulating layer 120B and the memory patterns 120A1 and 120A2 of the cell plug may include a blocking insulating layer 121 that is adjacent to the stack structure (e.g., 110B), a data storage layer 123 extending along an inner wall of the blocking insulating layer 121, and a tunnel insulating layer 125 extending along an inner wall of the data storage layer 123. The blocking insulating layer 121 may include an insulating material capable of blocking the movement of charges. The tunnel insulating layer 125 may include an insulating material through which charges can tunnel. The blocking insulating layer 121 may include an insulating layer having a high dielectric constant as compared with the tunnel insulating layer 125. The data storage layer 123 may be formed of a material layer capable of storing data that are changed using Fowler-Nordheim tunneling. In an embodiment, the data storage layer may be formed of an insulating layer including a charge trap insulating layer, a floating gate layer, or a conductive nano node. The charge trap insulating layer may include a silicon nitride layer. However, the present disclosure is not limited thereto, and the data storage layer 123 may be formed of a material layer capable of storing information based on another operation principle instead of Fowler-Nordheim tunneling. In an embodiment, the data storage layer 123 may include a phase change material layer, a ferroelectric layer, and the like.

The channel patterns 131A1 and 131A2 of the cell plug may be insulated from each other by the isolation structure 133. Each of the channel patterns 131A1 and 131A2 of the cell plug may be formed to have a thin thickness as compared with the semiconductor layer 131B on an inner wall of the tunnel insulating layer 125.

A central region of a tubular structure, which is defined by the semiconductor layer 131B, may be filled with the conductive pillar 113P. The semiconductor layer 131B and the conductive pillar 113P may be used as a conductive contact structure connected to the doped semiconductor structure DPS, shown in FIG. 4A or 4B.

FIGS. 7A and 7B are enlarged plan views illustrating a cross-section of each of the cell plug and the vertical structure. FIG. 7A illustrates a cross-section of each of the cell plug 130A and the vertical structure 130B at a level at which the second conductive layer 113B, shown in FIGS. 5 and 6, is disposed, and FIG. 7B illustrates a cross-section of each of the cell plug 130A and the vertical structure 130B at a level at which the second interlayer insulating layer 111B, shown in FIGS. 5 and 6, is disposed.

Referring to FIGS. 7A and 7B, each of the channel hole 115A and the auxiliary hole 115B may be formed in a structure having a major axis and a minor axis. The isolation structure 133 may include a core part 133P1 disposed in a central region of the channel hole 115A and two or more extension parts, for example, two extension parts 133P2, protruding to be in contact with a sidewall of the channel hole 115A. From a planar viewpoint, the extension parts 133P2 of the isolation structure 133 may be aligned on the minor axis of the channel hole 115A. The inside of the channel hole 115A may be isolated into two or more regions, for example, two regions AR1 and AR2, adjacent to a stack structure (e.g., 110B shown in FIG. 6) by the isolation structure 133. From a planar viewpoint, the two regions AR1 and AR2 may be aligned on the major axis of the channel hole 115A.

In an embodiment, each of the channel hole 115A and the auxiliary hole 115B may have an elliptical cross-section. The channel hole 115A may be isolated into a first region AR1 and a second region AR2. The first region AR1 and the second region AR2 may be aligned on a major axis of the elliptical cross-section. The first channel pattern 131A1 and the second channel pattern 131A2 may be respectively disposed in the first region AR1 and the second region AR2, and the first memory pattern 120A1 and the second memory pattern 120A2 may be respectively disposed in the first region AR1 and the second region AR2.

Each of the extension parts 133P2 of the isolation structure 133 may be interposed between the first channel pattern 131A1 and the second channel pattern 131A2. Each of the extension parts 133P2 of the isolation structure 133 may extend to be interposed between the first memory pattern 120A1 and the second memory pattern 120A2.

Each of the first memory pattern 120A1 and the second memory pattern 120A2 may include a first part PP1 and a second part PP2, which protrude toward the respective extension parts 133P2 of the isolation structure 133. Each of the first memory pattern 120A1 and the second memory pattern 120A2 may include a groove defined between the first part PP1 and the second part PP2. More specifically, the blocking insulating layer 121 of each of the first memory pattern 120A1 and the second memory pattern 120A2 may protrude farther toward the extension part 133P2 of the isolation structure 133 than the data storage layer 123 to form the first part PP1. The tunnel insulating layer 125 of each of the first memory pattern 120A1 and the second memory pattern 120A2 may protrude farther toward the extension part 133P2 of the isolation structure 133 than the data storage layer 123 to form the second part PP2. The groove of each of the first memory pattern 120A1 and the second memory pattern 120A2 may be defined between the blocking insulating layer 121 and the tunnel insulating layer 125.

The groove may be filled with the insulating layer 132. The insulating layer 132 may be formed of an insulating material that is different from an insulating material of an insulating pattern (e.g., 103B). The insulating layer 132 may be formed of an insulating material having an etch selectivity with respect to the insulating pattern (e.g., 103B). In an embodiment, the insulating layer 132 may include an oxide layer, such as a silicon oxide layer. The insulating layer 132 may be interposed between the data storage layer 123 of each of the first memory pattern 120A1 and the second memory pattern 120A2 and the extension part 133P2 of the isolation structure 133.

Each of the first channel pattern 131A1 and the second channel pattern 131A2 may be interposed between the core part 133P1 of the isolation structure 133 and a corresponding memory pattern 120A1 or 120A2. Each of the first channel pattern 131A1 and the second channel pattern 131A2 may have a cross-section having a curved shape. Each of the first channel pattern 131A1 and the second channel pattern 131A2 may include an end point that defines where the core part 133P1 and the extension part 133P2 converge. A thickness of each of the first channel pattern 131A1 and the second channel pattern 131A2 may be decreased as the channel patterns approach the that point at which the core part 133P1 and the extension part 133P2 of the isolation structure 133 converge. Each of the first channel pattern 131A1 and the second channel pattern 131A2 may have a maximum thickness D11 in a major axis direction of the channel hole 115A. In an embodiment, each of the first channel pattern 131A1 and the second channel pattern 131A2 may have a crescent-moon-shaped cross-section.

Like the first memory pattern 120A1 and the second memory pattern 120A2, the vertical insulating layer 120B may include a blocking insulating layer 121, a data storage layer 123, and a tunnel insulating layer 125, which are stacked on an inner wall of the auxiliary hole 115B. The vertical insulating layer 120B formed on the inner wall of the auxiliary hole 115B may have substantially the same thickness as each of the first memory pattern 120A1 and the second memory pattern 120A2, which are formed on an inner wall of the channel hole 115A.

The semiconductor layer 131B on an inner wall of the vertical insulating layer 120B may have different thicknesses in a major axis direction and a minor axis direction of the auxiliary hole 115B. Specifically, the semiconductor layer 131B may have a maximum thickness D12 in the major axis direction of the auxiliary hole 115B and may have a minimum thickness D22 in the minor axis direction of the auxiliary hole 115B. From a planar viewpoint, the maximum thickness D12 of the semiconductor layer 131B may be greater than the maximum thickness D11 of each of the first channel pattern 131A1 and the second channel pattern 131A2, and the minimum thickness D22 of the semiconductor layer 131B may be greater than a minimum thickness of each of the first channel pattern 131A1 and the second channel pattern 131A2.

According to the above-described structure, at the same level, a cross-sectional area of the first channel pattern 131A1 and the second channel pattern 131A2 of the cross-sectional area of the channel hole 115A may be smaller than a cross-sectional area of the semiconductor layer 131B of a cross-sectional area of the auxiliary hole 115B. At the same level, the auxiliary hole 115B may have substantially the same cross-sectional area as the channel hole 115A. Accordingly, at the same level, a cross-sectional area of the conductive pillar 113P may be smaller than a cross-sectional area of the isolation structure 133.

Referring to FIGS. 5, 6, 7A, and 7B, a column may be defined by channel holes, among the plurality of channel holes 115A, arranged in a line in the third direction DR3, and a column may be defined by auxiliary holes, among the plurality of auxiliary holes 115B, arranged in a line in the third direction DR3. FIGS. 5, 6, 7A, and 7B illustrate an embodiment in which the plurality of auxiliary holes 115B are arranged in a line in the third direction DR3 to form a single column, but the embodiment of the present disclosure is not limited thereto.

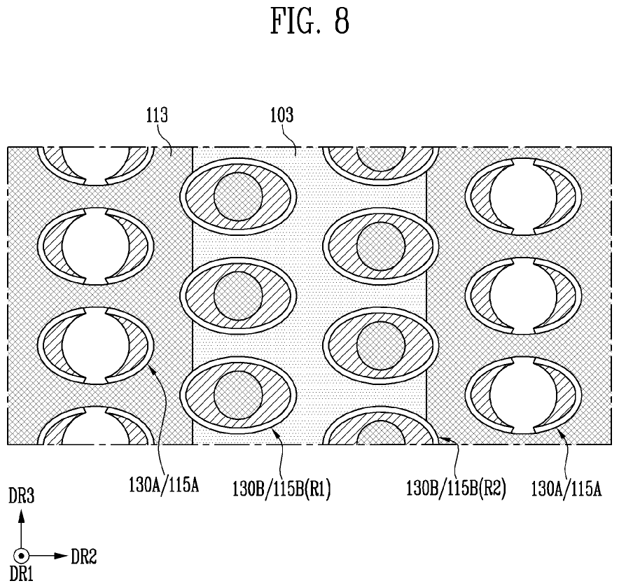

FIG. 8 is a plan view of a semiconductor memory device in accordance with an embodiment of the present disclosure. Hereinafter, overlapping descriptions components that are identical to those shown in FIGS. 5, 6, 7A, and 7B will be simplified or omitted.

Referring to FIG. 8, a conductive layer 113 of a gate stack structure may be penetrated by a plurality of channel holes 115A extending in the first direction DR1, and an insulating pattern 103 of the gate stack structure may be penetrated by a plurality of auxiliary holes 115B extending in the first direction DR1. The conductive layer 113 and the insulating pattern 103 may be adjacent to each other in the second direction DR2 and may have a plate shape extending in the second direction DR2 and the third direction DR3.

A column may be defined by channel holes, among the plurality of channel holes 115A, arranged in a line in the third direction DR3, a column may be defined by auxiliary holes, among the plurality of auxiliary holes 115B, arranged in a line in the third direction DR3. The number of columns of auxiliary holes disposed in the insulating pattern 103 may be varied. In an embodiment, the plurality of auxiliary holes 115B may include a first column R1 of auxiliary holes and a second column R2 of auxiliary holes. The first column R1 of the auxiliary holes and the second column R2 of the auxiliary holes may be adjacent to each other in the second direction DR2.

FIGS. 5, 6, 7A, 7B, and 8 illustrate an embodiment in which each of the channel hole 115A and the auxiliary hole 115B has an elliptical cross-section, but the embodiment of the preset disclosure is not limited thereto. The cross-section of each of the channel hole 115A and the auxiliary hole 115B may be formed in various shapes having major and minor axes. Like the channel hole 115A and the auxiliary hole 115B, a cross-section of each of a cell plug 130A and a vertical structure 130B may be formed in various shapes having major and minor axes.

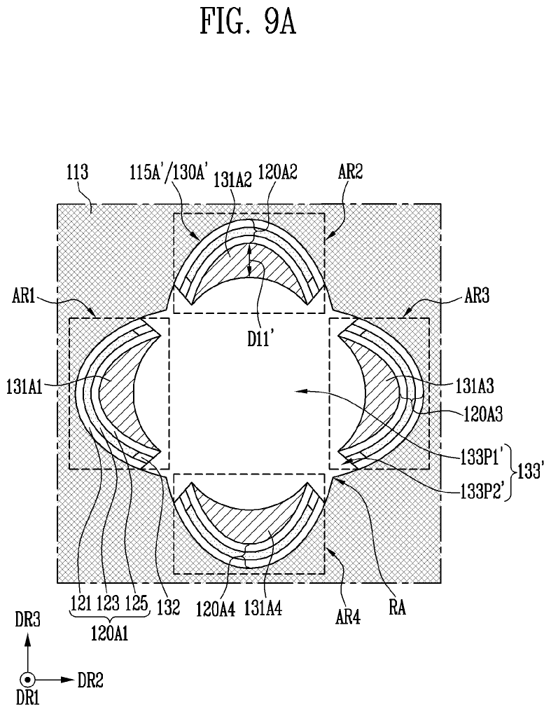

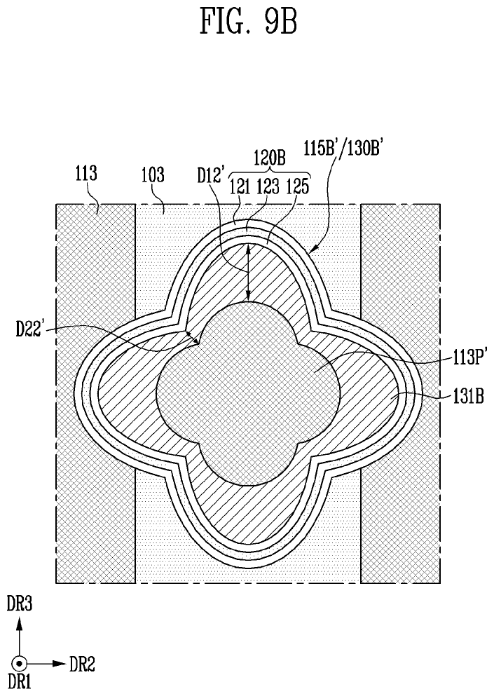

FIGS. 9A and 9B illustrate enlarged cross-sections of a cell plug and a vertical structure in accordance with an embodiment of the present disclosure. Detailed descriptions of technical features overlapping with the embodiments described with reference to FIGS. 5, 6, 7A, 7B, and 8 will be simplified or omitted.

Referring to FIGS. 9A and 9B, a conductive layer 113 of a gate stack structure may be penetrated by a channel hole 115A′ extending in the first direction DR1, and an insulating pattern 103 of the gate stack structure may be penetrated by an auxiliary hole 115B′ extending in the first direction DR1. The conductive layer 113 and the insulating pattern 103 may be adjacent to each other in the second direction DR2 and may have a plate shape extending in the second direction DR2 and the third direction DR3.

Referring to FIG. 9A, a cross-section of the channel hole 115A′ may be formed in a shape having a major axis and a minor axis. In an embodiment, from a planar viewpoint, the channel hole 115A′ may include a central region and three or more protrusion parts, for example, four protrusion parts, protruding in different directions from the central region. Each of the four protrusion parts may have a sidewall having a curved shape. A concave part RA may be defined between protrusion parts that are adjacent to each other.

A cell plug may include three or more channel patterns, three or more memory patterns, and an insulating layer. In an embodiment, a cell plug 130A′ may include four channel patterns 131A1, 131A2, 131A3, and 131A4, four memory patterns 120A1, 120A2, 120A3, and 120A4, and an insulating layer 132. The four channel patterns 131A1, 131A2, 131A3, and 131A4 may be respectively disposed inside the four protrusion parts of the channel hole 115A′. From a planar viewpoint, each of the four channel patterns 131A1, 131A2, 131A3, and 131A4 may have a thickness that becomes thinner as the channel patterns approach their corresponding end points. In an embodiment, each of the four channel patterns 131A1, 131A2, 131A3, and 131A4 may have a crescent-moon-shaped cross-section. The four memory patterns 120A1, 120A2, 120A3, and 120A4 may be respectively disposed inside the four protrusion parts of the channel hole 115A′. The insulating layer 132 may be disposed between each of the four memory patterns 120A1, 120A2, 120A3, and 120A4 and an isolation structure 133′.

The isolation structure 133′ may isolate the channel hole 115A′ into three or more regions. In an embodiment, the isolation structure 133′ may isolate the channel hole 115A′ into four regions AR1, AR2, AR3, and AR4. The four regions AR1, AR2, AR3, and AR4 may be respectively defined by the protrusion parts of the channel hole 115A′. In an embodiment, the channel hole 115A′ may include first to fourth protrusion parts protruding in different directions from the central region. Also, the channel hole 115A′ may be isolated into first to fourth regions AR1 to AR4 by the isolation structure 133′. In accordance with this embodiment, the four channel patterns 131A1, 131A2, 131A3, and 131A4 may include first to fourth channel patterns 131A1 to 131A4 respectively disposed in the first to fourth regions AR1 to AR4. The four memory patterns 120A1, 120A2, 120A3, and 120A4 may include first to fourth memory patterns 120A1 to 120A4 respectively disposed in the first to fourth regions AR1 to AR4.

The isolation structure 133′ may include a core part 133P1′ disposed in the central region of the channel hole 115A′ and an extension part 133P2′ protruding to be in contact with a sidewall of the channel hole 115A′ from the core part 133P1′. The extension part 133P2′ of the isolation structure 133′ may form a common surface with the concave part RA of the channel hole 115A′. The core part 133P1′ of the isolation structure 133′ may be formed in a convex shape toward the protrusion part of the channel hole 115A′.

Referring to FIG. 9B, at the same level, the auxiliary hole 115B′ may have the same cross-section as the channel hole 115A′ described with reference FIG. 9A. A vertical insulating layer 120B may continuously extend along an inner wall of the auxiliary hole 115B′ to be formed in a tubular shape. A semiconductor layer 131B may continuously extend along an inner wall of the vertical insulating layer 120B to be formed in a tubular shape. A conductive pillar 113P may fill a central region of a tubular structure defined by the vertical insulating layer 120B. The conductive pillar 113P′ may be formed in a convex shape toward the protrusion part of the channel hole 115A′.

Referring to FIGS. 9A and 9B, a thickness of each of the first to fourth channel patterns 131A1 to 131A4 may be decreased as the channel patterns approach that point at which the core part 133P1 and the extension part 133P2 of the isolation structure 133′ converge. Each of the first to fourth channel patterns 131A1 to 131A4 may have a maximum thickness D11′ in a major axis direction of the channel hole 115A′. The semiconductor layer 131B may have a maximum thickness D12′ in a major axis direction of the auxiliary hole 115B′ and may have a minimum thickness D22′ in a minor axis direction of the auxiliary hole 115B′. From a planar viewpoint, the maximum thickness D12′ of the semiconductor layer 131B may be greater than the maximum thickness D11′ of each of the first to fourth channel patterns 131A1 to 131A4, and the minimum thickness D22′ of the semiconductor layer 131B may be greater than a minimum thickness of each of the first to fourth channel patterns 131A1 to 131A4.

Each of the first to fourth memory patterns 120A1 to 120A4 and the vertical insulating layer 120B may include a blocking insulating layer 121, a data storage layer 123, and a tunnel insulating layer 125.

Hereinafter, a manufacturing method of a semiconductor memory device in accordance with an embodiment of the present disclosure will be described based on a manufacturing method of the semiconductor memory device, shown in FIGS. 5, 6, 7A, and 7B.

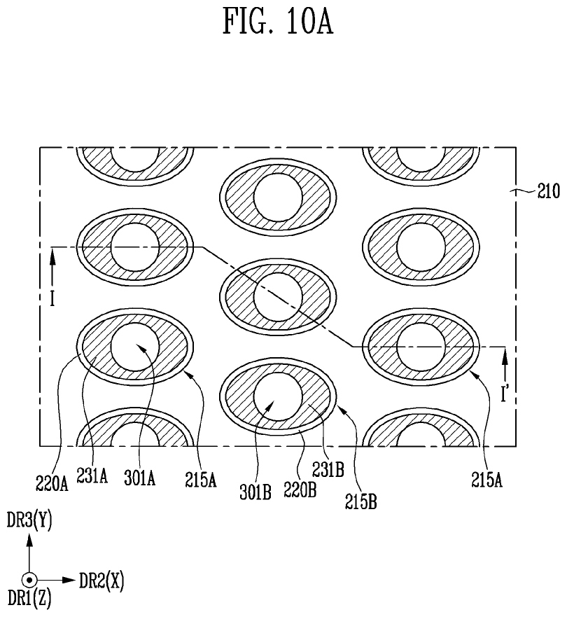

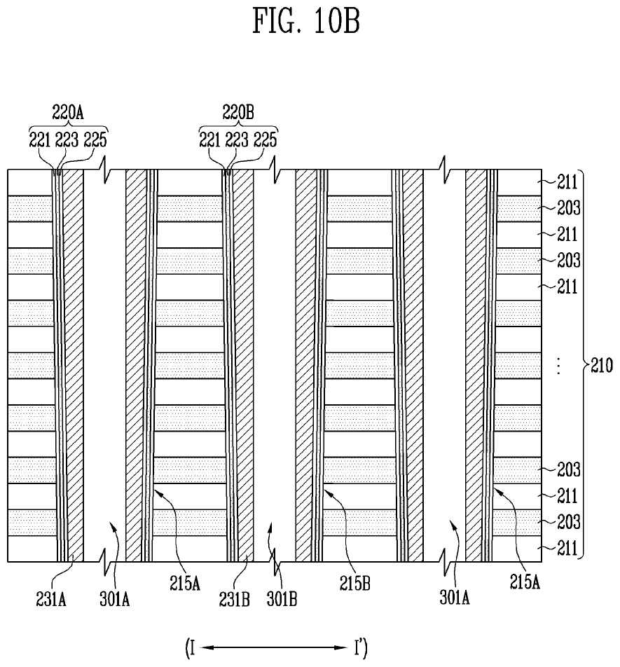

FIGS. 10A, 11A, 11B, 13A, 13B, 13C, 14, 15A, 16, 17A, and 17B are plan views illustrating a manufacturing method of a semiconductor memory device in accordance with an embodiment of the present disclosure.

FIGS. 10B, 12, 15B, and 17C are sectional views illustrating the manufacturing method of the semiconductor memory device in accordance with the embodiment of the present disclosure.

FIGS. 10A and 10B are plan and sectional views illustrating processes of forming a plurality of holes 215A and 215B, a memory layer 220A, a vertical insulating layer 220B, a channel layer 231A, and a semiconductor layer 231B. FIG. 10B is a sectional view taken along line I-I′, shown in FIG. 10A.

Referring to FIGS. 10A and 10B, a preliminary stack structure 210 may be formed on a lower structure (not shown). In an embodiment, the lower structure may be a sacrificial substrate formed of a silicon wafer or the like. The sacrificial substrate may be subsequently replaced with the doped semiconductor structure DPS, described with reference to FIG. 4B. In another embodiment, the lower structure may be a stack structure including the second structure ST2 and the doped semiconductor structure DPS, which are described with reference to FIG. 4A.

The preliminary stack structure 210 may be formed on the lower structure in accordance with the above-described various embodiments. The preliminary stack structure 210 may include a plurality of first material layers 211 and a plurality of second material layers 203, which are alternately disposed in the first direction DR1. Each of the first material layers 211 and the plurality of second material layers 203 may have a plate shape extending in the second direction DR2 and the third direction DR3.

The plurality of second material layers 203 may be formed of a material having an etch selectivity with respect to the plurality of first material layers 211. In an embodiment, the plurality of first material layers 211 may include an insulating material including a silicon oxide layer, a silicon oxynitride layer, and the like, and the plurality of second material layers 203 may include a sacrificial insulating material including a silicon nitride layer and the like.

Subsequently, a plurality of holes 215A and 215B may be formed in the preliminary stack structure 210. The process of forming the plurality of holes 215A and 215B may include a process of forming a mask pattern (not shown) on the preliminary stack structure 210 and a process of etching the first material layers 211 and the plurality of second material layers 203 by using the mask pattern as an etch barrier. Cross-sectional shapes of the plurality of holes 215A and 215B may be defined by the mask pattern. The plurality of holes 215A and 215B may penetrate the plurality of first material layers 211 and the plurality of second material layers 203. The cross-section of each of the plurality of holes 215A and 215B may have a structure having a major axis and a minor axis. In an embodiment, each of the plurality of holes 215A and 215B may have an elliptical cross-section. In another embodiment, each of the plurality of holes 215A and 215B may include a concave part RA, like the channel hole 115A′, shown in FIG. 9A.

The plurality of holes 215A and 215B may be arranged on a plurality of columns arranged along the second direction DR2. The plurality of holes 215A and 215B may be arranged in a line along the third direction DR3 on each column. The plurality of holes 215A and 215B may be divided into a plurality of channel holes 215A and a plurality of auxiliary holes 215B. The plurality of auxiliary holes 215B may constitute at least one column between columns configured with a plurality of channel holes 215A that are adjacent to each other. In another embodiment, like the first column R1 and the second column R2 of the plurality of auxiliary holes 115B, shown in FIG. 8, the plurality of auxiliary holes 215B may constitute a first column and a second column between columns of a plurality of channel holes 215A that are adjacent to each other.

After the plurality of channel holes 215A and the plurality of auxiliary holes 215B are formed, a blocking insulating layer 221, a data storage layer 223, and a tunnel insulating layer 225 may be sequentially formed on a sidewall of each of the plurality of channel holes 215A and the plurality of auxiliary holes 215B. The blocking insulating layer 221 may be formed on the sidewall of each of the plurality of channel holes 215A and the plurality of auxiliary holes 215B. The data storage layer 223 may be formed on an inner wall of the blocking insulating layer 221. The tunnel insulating layer 225 may be formed on an inner wall of the data storage layer 223. The blocking insulating layer 221, the data storage layer 223, and the tunnel insulating layer 225 may include the same materials as the blocking insulating layer 121, the data storage layer 123, and the tunnel insulating layer 125, which are described with reference to FIG. 6. The blocking insulating layer 221, the data storage layer 223, and the tunnel insulating layer 225 may be divided into a memory layer 220A disposed on the sidewall of each of the plurality of channel holes 215A and a vertical insulating layer 220B disposed on the sidewall of each of the plurality of auxiliary holes 215B.

Subsequently, a tubular layer may be formed on an inner wall of the tunnel insulating layer 225. A deposition amount of the tubular layer may be controlled to have a thick thickness in a direction in which the major axis, defined by the cross-section of each of the channel hole 215A and the auxiliary hole 215B, faces as compared with a direction in which the minor axis, defined by the cross-section, faces. The tubular layer may be divided into a channel layer 231A on an inner wall of the memory layer 220A and a semiconductor layer 231B on an inner wall of the vertical insulating layer 220B. A central region of the channel hole 215A, which is opened by the channel layer 231A, may be defined as a first opening 301A, and a central region of the auxiliary hole 215B, which is opened by the semiconductor layer 231B, may be defined as a second opening 301B. Each of the channel layer 231A and the semiconductor layer 231B may include silicon (Si), germanium (Ge), or a mixture thereof.

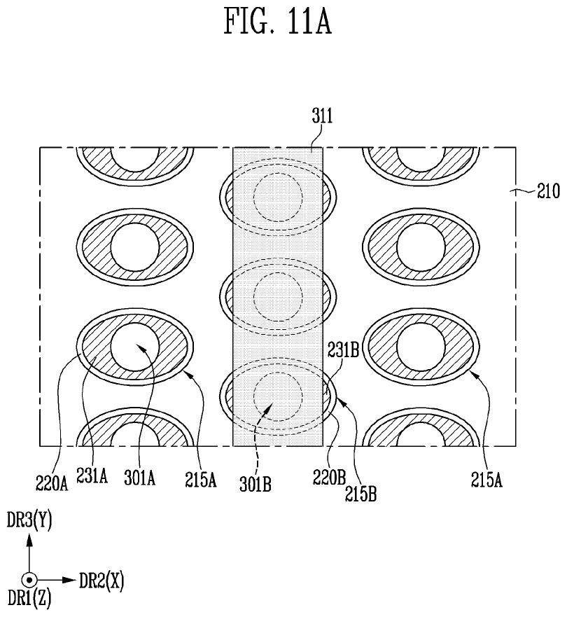

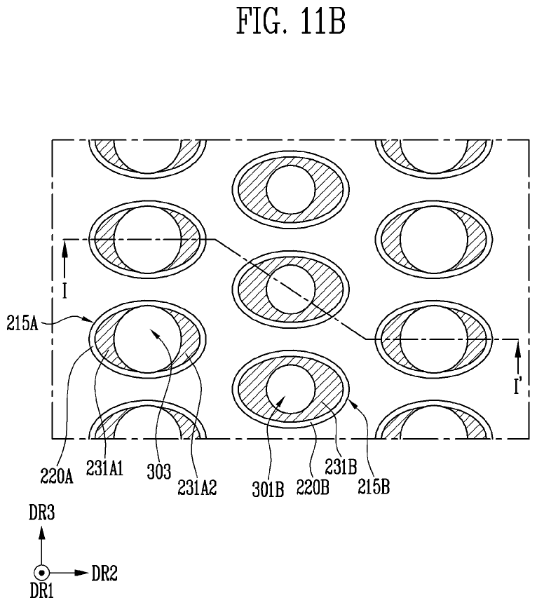

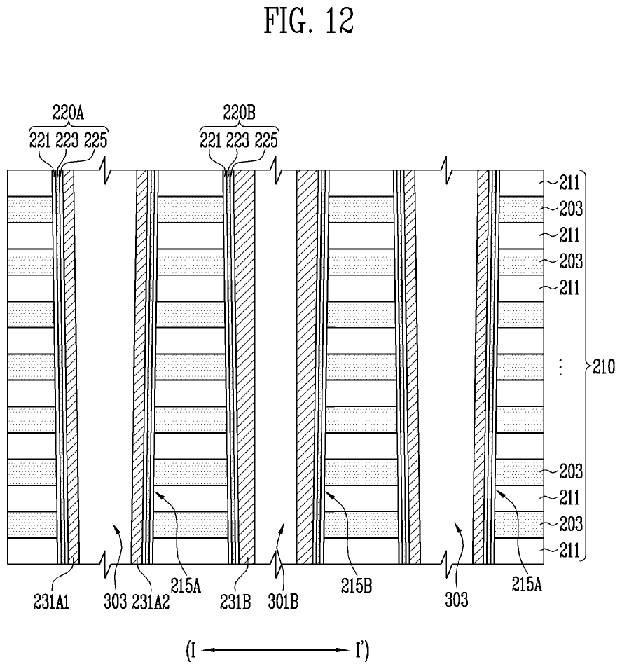

FIGS. 11A and 11B are plan views illustrating a process of isolating the channel layer 231A into two or more channel patterns, for example, two channel patterns 231A1 and 231A2, and FIG. 12 is a sectional view taken along line I-I′, shown in FIG. 11B.

Referring to FIG. 11A, a mask pattern 311 may be formed on the preliminary stack structure 210 such that the second opening 301B of each of the plurality of auxiliary holes 215B is blocked. Subsequently, a portion of the channel layer 231A may be etched from an inner wall of the channel layer 231A through the first opening 301A of each of the plurality of channel holes 215A.

Referring to FIGS. 11B and 12, an etched thickness of the channel layer 231A, shown in FIG. 11A, may be controlled within a range in which the etched thickness of the channel layer 231A is greater than a first thickness of the channel layer 231A in a minor axis direction of the channel hole 215A and is smaller than a second thickness of the channel layer 231A in a major axis direction of the channel hole 215A. As the result of an etching process of the channel layer 231A in which the etched thickness is controlled as described above, the channel layer 231A, shown in FIG. 11A, may be isolated into two channel patterns 231A1 and 231A2, and a portion of the memory layer 220A may be exposed between channel patterns that are adjacent to each other among the two channel patterns 231A1 and 231A2. The mask pattern 311 shown in FIG. 11A may be removed after the channel layer 231A shown in FIG. 11A is isolated into the two channel patterns 231A1 and 231A2.

The two channel patterns 231A1 and 231A2 may be arranged along the sidewall of the channel hole 215A. In an embodiment, when the channel hole 215A has an elliptical cross-section, the channel layer 231A, shown in FIG. 11A, may be isolated into a first channel pattern 231A1 and a second channel pattern 231A2. However, the embodiment of the present disclosure is not limited thereto. In another embodiment, when the channel hole 215A includes a concave part RA and first to fourth protrusion parts, like the channel hole 115A′, shown in FIG. 9A, the channel layer 231A, shown in FIG. 11A, may be isolated into first to fourth channel patterns 131A1 to 131A4 as shown in FIG. 9A.

As the channel layer 231A is etched, the first opening 301A, shown in FIG. 11A, may be expanded. Hereinafter, the expanded first opening 301A is defined as a third opening 303.

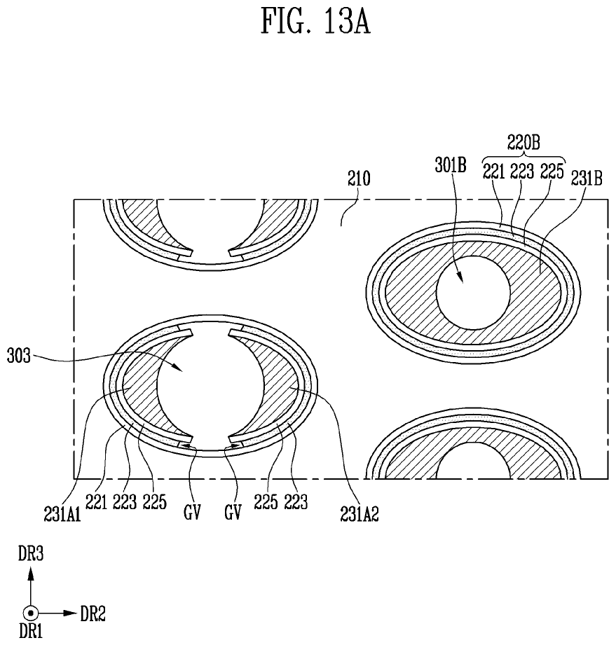

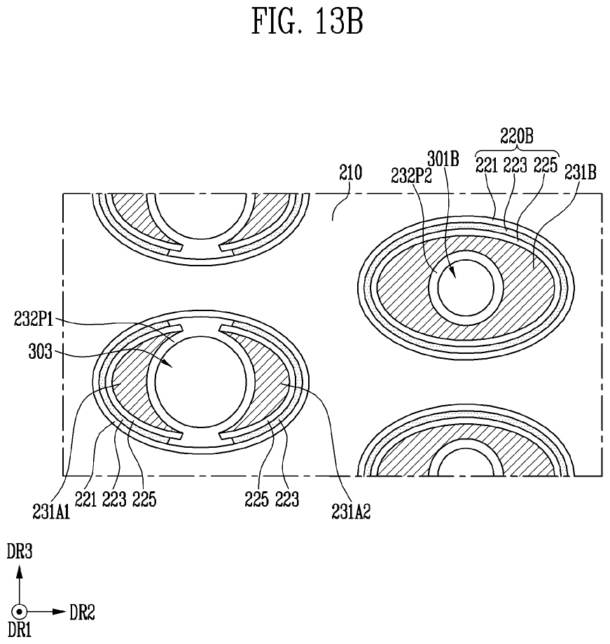

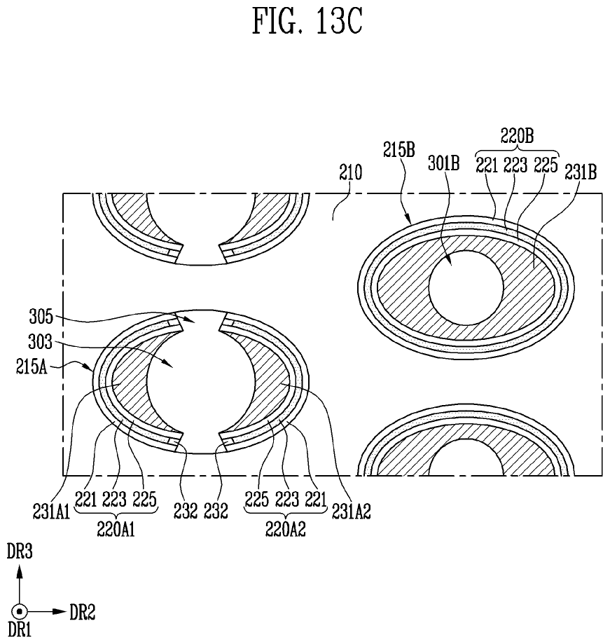

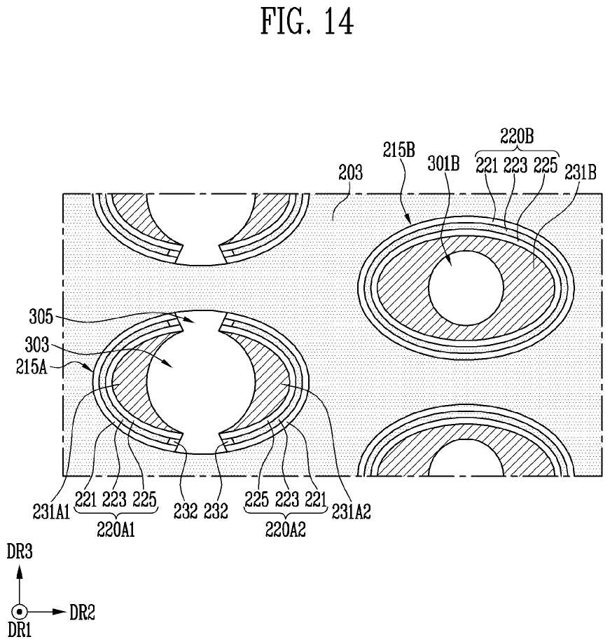

FIGS. 13A, 13B, 13C, and 14 are plan views illustrating a process of isolating the memory layer 220A, shown in FIG. 12, into two or more memory patterns, for example, two memory patterns 220A1 and 220A2. FIGS. 13A to 13C and 14 are enlarged views illustrating second and third openings 301B and 303 that are adjacent to each other and regions that are adjacent thereto.

Referring to FIG. 13A, a portion of the memory layer 220A shown in FIGS. 11B and 12 may be exposed through the third opening 303 and may be etched through an etching process. In an embodiment, the tunnel insulating layer 225 and the data storage layer 223 of the memory layer 220A, shown in FIGS. 11B and 12, may be sequentially etched through the third opening 303. The data storage layer 223 of the memory layer 220A, shown in FIGS. 11B and 12, may be etched through a selective etching process such that a groove GV is defined. The groove GV may be defined between the tunnel insulating layer 225 and the blocking insulating layer 221 of the memory layer 220A, shown in FIGS. 11B and 12.

While the tunnel insulating layer 225 and the data storage layer 223 of the memory layer 220A, shown in FIGS. 11B and 12, are etched, the tunnel insulating layer 225 and the data storage layer 223 of the vertical insulating layer 220B may be protected by the semiconductor layer 231B.

Referring to FIG. 13B, a liner layer may be formed along an inner wall of each of the third opening 303 and the second opening 301B such that the groove GV, shown in FIG. 13A, is filled. The liner layer may be formed of an insulating material having an etch selectivity with respect to the plurality of second material layers 203, shown in FIG. 12. In an embodiment, the liner layer may be formed of an oxide layer such as a silicon oxide layer. The liner layer may be divided into a first pattern 232P1 formed along the inner wall of the third opening 303 and a second pattern 232P2 formed along the inner wall of the second opening 301B.

FIG. 13C is a plan view illustrating a subsequent process after the process described with reference to FIG. 13B. FIG. 14 is a plan view illustrating the preliminary stack structure 210, shown in FIG. 13C, at a level at which the second material layer 203 is disposed.

Referring to FIGS. 13C and 14, the first pattern 232P1 and the second pattern 232P2, which are shown in FIG. 13B, may be etched through the third opening 303 and the second opening 301B. A portion of the blocking insulating layer 221 may be etched through a space between channel patterns that are adjacent to each other, among the two channel patterns 231A1 and 231A2, and a fourth opening 305 may be defined. The fourth opening 305 may be connected to the third opening 303 and may be aligned on the minor axis of the channel hole 215A.

A portion of the first pattern 232P1, shown in FIG. 13B, may remain as an insulating layer 232 inside the groove GV, shown in FIG. 13A. The second pattern 232P2, shown in FIG. 13B, may be removed such that an inner wall of the semiconductor layer 231 is exposed through the second opening 301B.

The memory layer may be isolated into the two memory patterns 220A1 and 220A2 by the fourth opening 305. The two memory patterns 220A1 and 220A2 may be respectively disposed between the sidewall of the channel hole 215A and the two channel patterns 231A1 and 231A2, respectively. In an embodiment, when the channel hole 215A has an elliptical cross-section, the memory layer may be isolated into a first memory pattern 220A1 between the first channel pattern 231A1 and the sidewall of the channel hole 215A and a second memory pattern 220A2 between the second channel pattern 231A2 and the sidewall of the channel hole 215A. However, the embodiment of the present disclosure is not limited thereto. In another embodiment, when the channel hole 215A includes a concave part RA and first to fourth protrusion parts, like the channel hole 115A′ as shown in FIG. 9A, the memory layer may be isolated into first to fourth memory patterns 120A1 to 120A4 as shown in FIG. 9A.

A side part of the preliminary stack structure 210 may be exposed through the fourth opening 305. In particular, the second material layer 203 of the preliminary stack structure 210 may be exposed through the fourth opening 305. In accordance with an embodiment of the present disclosure, the fourth opening 305 may be automatically aligned between memory patterns (e.g., 220A1 and 220A2) that are adjacent to each other.

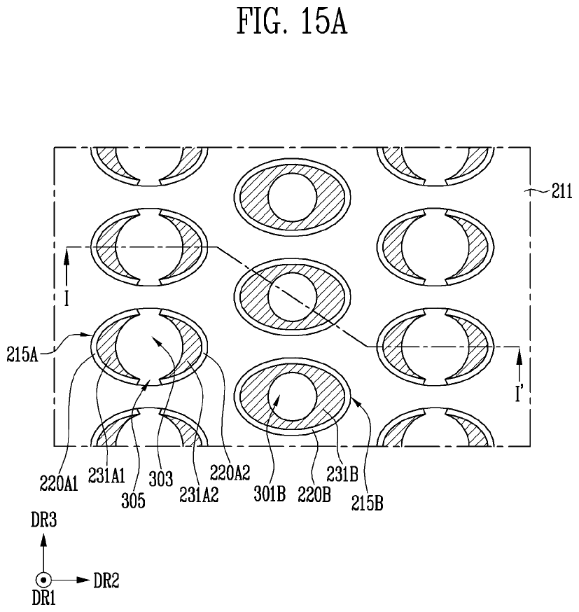

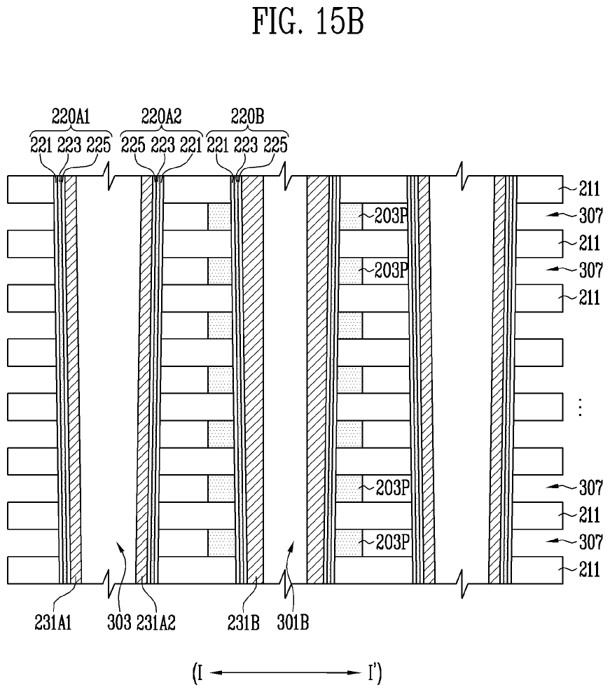

FIGS. 15A and 15B are plan and sectional views illustrating a process of forming insulating patterns 203P. FIG. 15B is a sectional view taken along line I-I′, shown in FIG. 15A.

Referring to FIGS. 15A and 15B, a portion of the second material layer 203 at the periphery of the channel hole 215A, shown in FIG. 14, may be etched through the fourth opening 305 of the channel hole 215A. Accordingly, a fifth opening 307 may be formed between first material layers 211, among the plurality of first material layers 211 adjacent to each other in the first direction DR1. The second material layer 203, shown in FIG. 14, may remain as an insulating pattern 203P at the periphery of the plurality of auxiliary holes 215B.

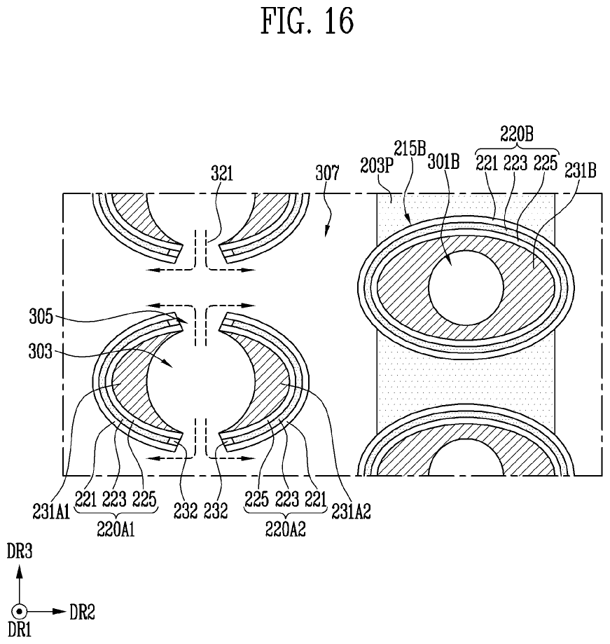

FIG. 16 is a plan view at a level at which the insulating pattern 203P, shown in FIG. 15B, is disposed and is an enlarged view illustrating the insulating pattern 203P and a region at the periphery of the insulating pattern 203P.

Referring to FIGS. 15A, 15B, and 16, an etching material that selectively etches the second material 203, shown in FIG. 14, may be provided to remove a partial region of the second material layer 203 disposed at a certain distance from the fourth opening 305 along a path 321 indicated by a dotted line. The insulating pattern 203P formed of the remaining second material layer may remain between auxiliary holes 215 that are adjacent to each other, among the plurality of auxiliary holes 215B.

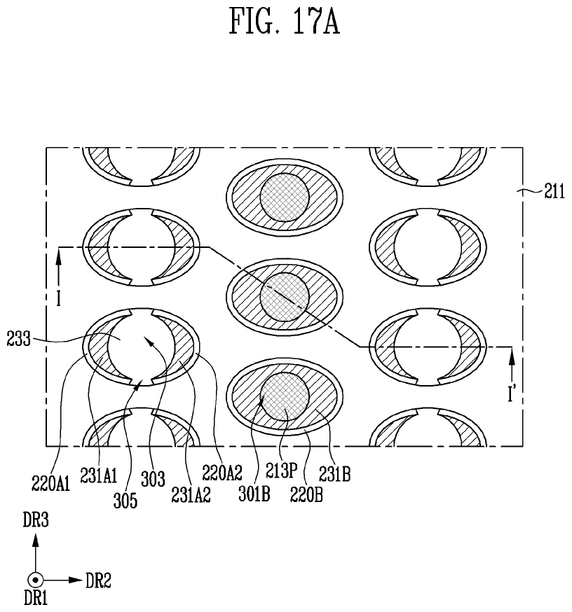

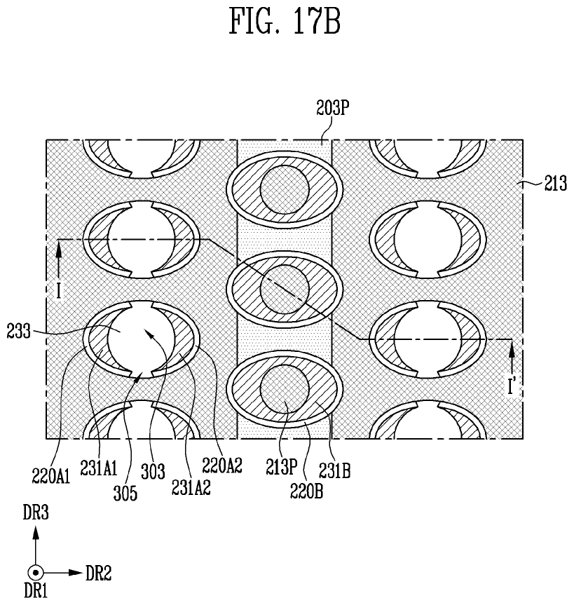

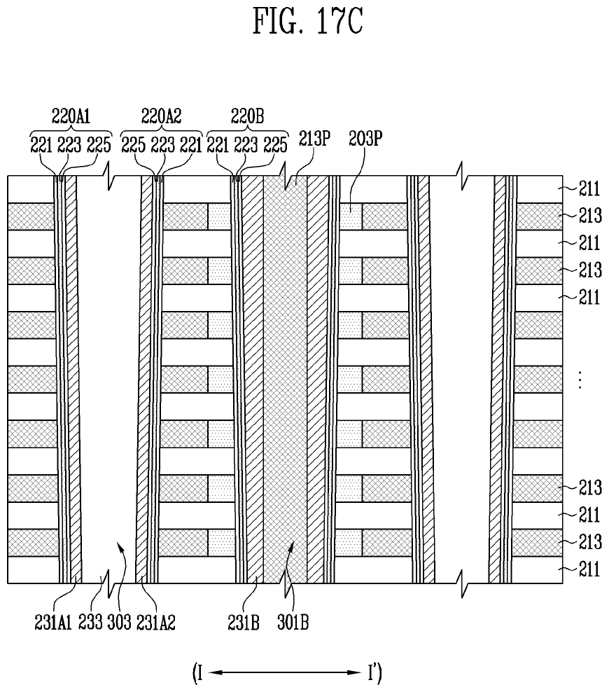

FIGS. 17A, 17B, and 17C are views illustrating a process of forming a conductive layer 213 and a conductive pillar 213P. FIG. 17A is a plan view at a level at which the first material layer 211 is disposed, FIG. 17B is a plan view at a level at which the conductive layer 213 and the insulating pattern 203P are disposed, and FIG. 17C is a sectional view taken along line I-I′, shown in FIGS. 17A and 17B.

Referring to FIGS. 17A to 17C, the fifth opening 307 and the second opening 301B, which are shown in FIGS. 15A and 16, may be filled with a conductive material. The conductive material may include at least one of a doped semiconductor layer, a metal layer, and a conductive metal nitride layer.

Subsequently, the conductive material inside the third opening 303 and the fourth opening 305 may be removed such that the conductive material is isolated into a plurality of conductive layers 213. The conductive material disposed in a central region of the semiconductor layer 231B may remain as a conductive pillar 213P.

In accordance with the embodiment of the present disclosure, although a separate etching process for forming a slit extending to penetrate the stack structure is not performed, the conductive layers 213 disposed at the same level may be insulated from each other through the insulating pattern 203P. Thus, in the embodiment of the present disclosure, processes accompanied to form the above-described slit may be omitted, and a vertical etching process having a high level of difficulty may be reduced. Accordingly, the stability of a manufacturing process of the semiconductor memory device may be improved. Also, in accordance with the embodiment of the present disclosure, a margin for securing a disposition space for the slit does not need to be considered, and thus, the level of difficulty of the manufacturing process of the semiconductor memory device may be reduced.

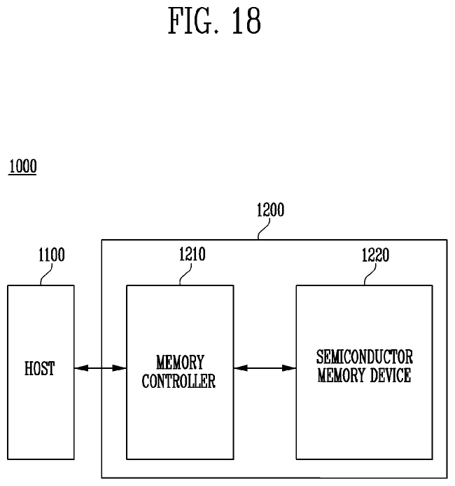

FIG. 18 is a block diagram illustrating an electronic system including a semiconductor memory device in accordance with embodiments of the present disclosure.

Referring to FIG. 18, the electronic system 1000 may be a computing system, a medical device, a communication device, a wearable device, a memory system, or the like. The electronic system 1000 may include a host 1100 and a storage device 1200.

Based on an interface, the host 1100 may store data in the storage device 1200 or read data stored in the storage device 1200. The interface may include at least one of a Double Data Rate (DDR) interface, a Universal Serial Bus (USB) interface, a Multi-Media Card (MMC) interface, an embedded MMC (eMMC) interface, a Peripheral Component Interconnection (PCI) interface, a PCI-Express (PCI-E) interface, an Advanced Technology Attachment (ATA) interface, a Serial ATA (SATA) interface, a Parallel ATA (PATA) interface, a Small Computer System Interface (SCSI), an Enhanced Small Disk Interface (ESDI), an Integrated Drive Electronics (IDE) interface, a firewire interface, a Universal Flash Storage (UFS) interface, and a Non-Volatile Memory express (NVMe) interface.

The storage device 1200 may include a memory controller 1210 and a semiconductor memory device 1220. In an embodiment, the storage device 1200 may be a storage medium, such as a Solid State Drive (SSD) or a Universal Serial Bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a nonvolatile memory device. The semiconductor memory device 1220 may include the semiconductor memory device described with reference to FIGS. 5 and 6, and a cell plug and a vertical structure of the semiconductor memory device 1220 may have the structure and arrangement, shown in FIGS. 7A and 7B, have the arrangement shown in FIG. 8, or have the structure shown in FIGS. 9A and 9B. In an embodiment, the semiconductor memory device 1220 may include a plurality of conductive layers stacked to be spaced apart from each other in a first direction, a channel hole extending in the first direction to penetrate the plurality of conductive layers, two or more channel patterns disposed to be spaced apart from each other along a sidewall of the channel hole, and two or more memory patterns disposed to be spaced apart from each other between the sidewall of the channel hole and the two or more channel patterns, respectively.

According to various embodiments of the present disclosure, two or more memory cells may be formed along a channel hole in one conductive layer, and thus, the degree of integration of memory cells may be improved.

According to various embodiments of the present disclosure, a process of forming a slit for replacing a material layer of a stack structure with a conductive layer may be omitted, and thus the level of difficulty of a manufacturing process may be reduced.

What is claimed is:

1. A semiconductor memory device comprising:
a stack structure including a plurality of conductive layers stacked to be spaced apart from each other in a first direction;
a channel hole extending in the first direction to penetrate the plurality of conductive layers in the stack structure;
an isolation structure including a core part disposed in a central region of the channel hole and an extension part protruding from the core part toward a sidewall of the channel hole, the isolation structure isolating the channel hole into two or more regions that are adjacent to the stack structure;
a channel pattern disposed in each of the two or more regions of the channel hole;
a memory pattern interposed between the channel pattern and the stack structure, the memory pattern including a first part and a second part, which protrude toward the extension part of the isolation structure; and
an insulating layer filling a groove defined between the first part and the second part of the memory pattern.

2. The semiconductor memory device of claim 1, wherein the channel pattern is interposed between the memory pattern and the core part of the isolation structure,
wherein the channel pattern includes an end point that defines where the core part and the extension part converge, and
wherein the extension part of the isolation structure includes two or more extensions.

3. The semiconductor memory device of claim 2, wherein a thickness of the channel pattern decreases as the channel pattern approaches the end point at which the core part and the extension part of the isolation structure converge.

4. The semiconductor memory device of claim 1, wherein the channel pattern has a crescent-moon-shaped cross-section.

5. The semiconductor memory device of claim 1, wherein the memory pattern includes:
a blocking insulating layer adjacent to the stack structure;
a data storage layer extending along an inner wall of the blocking insulating layer; and
a tunnel insulating layer extending along an inner wall of the data storage layer,
wherein the blocking insulating layer protrudes farther toward the extension part of the isolation structure than the data storage layer to form the first part of the memory pattern, and
wherein the tunnel insulating layer protrudes farther toward the extension part of the isolation structure than the storage data layer to form the second part of the memory pattern.

6. The semiconductor memory device of claim 5, wherein the insulating layer is interposed between the data storage layer and the extension part of the isolation structure.

7. The semiconductor memory device of claim 1, wherein the channel hole has an elliptical cross-section,
wherein the extension part of the isolation structure is aligned on a minor axis of the elliptical cross-section, and
wherein the two or more regions include a first region and a second region, which are aligned on a major axis of the elliptical cross-section.

8. The semiconductor memory device of claim 1, wherein, from a planar viewpoint, the channel hole includes a plurality of protrusion parts protruding in different directions from the central region,
wherein the plurality of protrusion parts include a first protrusion part and a second protrusion part,
wherein the channel hole further includes a concave part defined between the first protrusion part and the second protrusion part,
wherein the extension part of the isolation structure forms a common surface with the concave part of the channel hole, and
wherein the two or more regions are respectively defined by the plurality of protrusion parts of the channel hole.

9. The semiconductor memory device of claim 1, wherein the stack structure further includes:
a plurality of insulating patterns adjacent to the plurality of conductive layers in a second direction, the plurality of insulating patterns being stacked to be spaced apart from each other in the first direction; and
a plurality of interlayer insulating layers alternately disposed with the plurality of conductive layers in the first direction, the plurality of interlayer insulating layers extending in the second direction to overlap with the plurality of insulating patterns.

10. The semiconductor memory device of claim 9, further comprising:
an auxiliary hole extending in the first direction to penetrate the plurality of interlayer insulating layers and the plurality of insulating patterns in the stack structure;
a conductive pillar disposed in a central region of the auxiliary hole;
a vertical insulating layer extending along a sidewall of the auxiliary hole; and
a semiconductor layer disposed between the vertical insulating layer and the conductive pillar, the semiconductor layer surrounding the conductive pillar.

11. The semiconductor memory device of claim 10, wherein, from a planar viewpoint, a minimum thickness of the semiconductor layer is greater than a minimum thickness of the channel pattern, and a maximum thickness of the semiconductor layer is greater than a maximum thickness of the channel pattern.

12. The semiconductor memory device of claim 10, wherein the auxiliary hole has substantially the same cross-sectional shape as the channel hole.

13. The semiconductor memory device of claim 10, wherein the conductive pillar includes the same conductive material as the plurality of conductive layers.

14. The semiconductor memory device of claim 10, wherein a cross-sectional area of the conductive pillar is smaller than a cross-sectional area of the isolation structure.

15. A semiconductor memory device comprising:
a stack structure including a plurality of conductive layers stacked to be spaced apart from each other in a first direction and a plurality of insulating patterns that are adjacent to the plurality of conductive layers in a second direction, the plurality of insulating patterns being stacked to be spaced apart from each other in the first direction;
a plurality of channel holes extending in the first direction to penetrate the plurality of conductive layers in the stack structure;
a cell plug formed in each of the plurality of channel holes, the cell plug including two or more channel patterns isolated from each other along a sidewall of each of the plurality of channel holes and two or more memory patterns disposed between the sidewall of each of the plurality of channel holes and the two or more channel patterns, respectively, the two or more memory patterns being isolated from each other;
a plurality of auxiliary holes extending in the first direction to penetrate the plurality of insulating patterns in the stack structure; and
a vertical structure including a tubular semiconductor layer disposed inside each of the plurality of auxiliary holes and a tubular vertical insulating layer disposed outside of the tubular semiconductor layer.

16. The semiconductor memory device of claim 15, wherein the cell plug further includes an isolation structure including a core part disposed in a central region of each of the plurality of channel holes and an extension part protruding from the core part to be interposed between memory patterns that are adjacent to each other, among the two or more memory patterns.

17. The semiconductor memory device of claim 16, wherein each of the two or more memory patterns includes a first part and a second part, which protrude toward the extension part of the isolation structure, and
wherein the cell plug further includes an insulating layer filling a groove defined between the first part and the second part of each of the two or more memory patterns.

18. The semiconductor memory device of claim 15, wherein the vertical structure further includes a conductive pillar disposed in a central region of the tubular semiconductor layer.

19. The semiconductor memory device of claim 15, wherein the plurality of auxiliary holes are arranged in a line in a third direction to form a single column.

20. The semiconductor memory device of claim 15, wherein the plurality of auxiliary holes form a first column of auxiliary holes arranged in a line in a third direction and a second column of auxiliary holes arranged in a line in the third direction, and
wherein the first column of the auxiliary holes and the second column of the auxiliary holes are adjacent to each other in the second direction.
